(19) United States
(12) Patent Application Publication
(10) Pub. No.: US 2005/0056827 A1
(43) Pub. Date: Mar. 17, 2005

(54) CMOS compatible low band offset double barrier resonant tunneling diode

(75) Inventors: Ming Fu Li, Singapore (SG); Jagar Singh, Singapore (SG); Yong Tian Hou, Singapore (SG); Narayanan Balasubramanian, Singapore (SG); Fujiang Lin, Singapore (SG)

Correspondence Address: STEPHEN B. ACKERMAN, 28 DAVIS AVENUE, POUGHKEEPSIE, NY, 12603, US

(73) Assignees: Agency For Science, Technology And Research; National University of Singapore

(21) Appl. No.: 10/767,275

(22) Filed: Jan. 29, 2004

Related U.S. Application Data
(60) Provisional application No. 60/503,110, filed on Sep. 15, 2003.

(51) Int. Cl. H01L 29/06

(52) U.S. Cl. 257/25

(57) ABSTRACT

Three configurations of double barrier resonant tunneling diodes (RTD) are provided along with methods of their fabrication. The tunneling barrier layers of the diode are formed of low band offset dielectric materials and produce a diode with good I-V characteristics including negative differential resistance (NDR) with good peak-to-valley ratios (PVR). Fabrication methods of the RTD start with silicon-on-insulator substrates (SOI), producing silicon quantum wells, and are, therefore, compatible with main stream CMOS technologies such as those applied to SOI double gate transistor fabrication. Alternatively, Ge-on-insulator or SiGe-on-insulator substrates can be used if the quantum well is to be formed of Ge or SiGe. The fabrication methods include the formation of both vertical and horizontal silicon quantum well layers. The vertically formed layer may be oriented so that its vertical sides are in any preferred crystallographic plane, such as the 100 or 110 planes.

This application claims priority to U.S. Provisional Application No. 60/503,110, filed on Sep. 15, 2003 and which is fully incorporated herein by reference.

### BACKGROUND OF THE INVENTION

1. Field of the Invention

This invention relates to solid state electronics, in particular to a novel high frequency silicon based resonant tunnel diode with negative differential resistance.

2. Description of the Related Art

The tunnel diode formed by a heavily doped p-n junction was invented by Esaki in 1958. This diode operated on the basis of interband tunneling, wherein charge carriers moved between valence and conduction bands by tunneling through an intervening potential barrier. Subsequently, in 1974, Esaki and co-workers demonstrated a resonant tunneling diode (RTD) consisting of two potential barriers separated by a potential well using a III-V compound semiconductor (L. L Chang, L. Esaki, and R. Tsu, “Resonant tunneling in the semiconductor double barriers,” Appl. Phys. Lett., Vol. 24, pp. 593-595, June 1974). In this device, the tunneling was intraband, between conduction and conduction or valence and valence bands, through an intermediate quantum well whose bound state energies corresponded to those energies of injected electrons which would have the maximum probability for tunneling.

Over the past three decades, RTDs exhibiting negative differential resistance (NDR) have received a great deal of attention due to their potential for application in electronics. Since the RTD offers the capability of operation as an oscillator, an amplifier and a mixer at extremely high frequency and with high resonant current density and very low noise, its implementation in integrated circuits would minimize the total device counts, and standby current. Indeed, Noble (U.S. Pat. No. 6,208,555) provides an SRAM memory cell that includes two tunnel diodes coupled in series and a MOSFET. RTDs with good I-V characteristics have been demonstrated in heteroeptaxial systems such as GaAs/AlGaAs/GaAs (Dong-Joon Kim, Yong-Tae Moon, Keun-Man Song and Seong-Ju Park, “Effect of barrier thickness on the interface and optical properties of InGaN/GaN multiple quantum wells,” Jpn. J. Appl. Phys., Part 1, 40, 3085 (2001)) and SiGe/Si (U.S. Published patent application No. 2003/0049894) and will be briefly discussed below. In addition, Bate et al. (European Published Application No. 94107763.8, Publication No. 0 668 618 A2) discloses a resonant tunneling device in which a silicon well is sandwiched between epitaxially grown layers of CaF₂.

However, RTDs have been difficult to integrate into mainstream Si CMOS IC technology. In the RTD structure, the silicon film is sandwiched on each side by a SiO₂ dielectric layer. The quantum barrier is made from this dielectric film, which has a relatively larger band gap than silicon. SiO₂ is not the only material suitable for the barrier layer that has a wider band gap than silicon. The difference in the band gap between the silicon and its surrounding barrier layers results in a positive conduction band-offset (difference between the conduction band edge and barrier height) with respect to the smaller band gap of Si. The silicon layer between the two barriers, which has a width close to the electron's deBroglie wavelength, forms a quantum well which supports a band containing several discrete electron energy levels that may be broadened by various processes. The electron transport across the barrier occurs by means of this energy band, which, by its presence, promotes the tunneling of injected electrons and produces a corresponding tunneling current when an appropriate bias voltage is applied. When the band energy of the well is close to the conduction electron energy of the emitter electrode (the “resonance” referred to in the device name), the maximum tunneling current is produced. This current decreases as the conduction electron energy departs from the energy in the band due to the applied bias. This reduction in current as the voltage is increased gives rise to what is called the negative differential resistance (NDR) behavior in the I-V characteristics of the tunnel diode. It should be noted that the valuable negative differential resistance characteristics of tunnel diodes, which is the property to be developed in the present invention, is not confined to the tunnel diode or the resonant tunneling diode. King et al. (U.S. Pat. No. 6,512,274) teaches the formation of an n-channel metal-insulator-semiconductor field effect transistor (MISFET), which also exhibits the NDR property. King et al. (European Published Application No. 01105228.9, Publication No. EP 1 168 456 A2) discloses a n-channel MISFET NDR device and the method of its operation. Suzuki et al. (U.S. Pat. No. 6,528,370) teach the formation of a device that includes a conducting channel layer, a floating region (insulated from the channel) above the channel layer and a quantum well region disposed between the floating region and the channel layer. In this device, the drain voltage vs. drain current curve displays the characteristic negative resistance shape.

Although the SiO₂ double barrier structure with a silicon well was reported in H. Ikeda, M. Iwasaki, Y. Ishikawa, and M. Tabe, “Resonant tunneling characteristics in SiO2/Si double barrier structure in a wide range of applied voltage,” Applied Physics Letters, vol.83, pp.1456-1458, 2003, it remains a challenge for SiO₂/Si type RTDs to find their way into applications due to poor performance which is due mainly to the large band offset between SiO₂ and Si and the excessive thickness SiO₂ of the buried oxide layer in a silicon-on-insulator (SOI) substrate. Okuno, in both (U.S. Pat. No. 5,466,949) and (U.S. Pat. No. 5,616,515) discloses a resonant tunneling diode formed by layering silicon dioxide barrier layers on either side of a germanium well, but, as already noted, this device structure is not compatible with silicon processing schemes. Harvey et al. (U.S. Pat. No. 6,239,450) disclose a negative differential resistance type device formed by inducing the growth of silicon crystalline microclusters within a matrix of amorphous silicon. The fabrication of such a device would not fit smoothly within the convention silicon process flow scheme. Wallace et al. (U.S. Pat. No. 5,606,177) discloses a resonant tunnel diode made of a silicon quantum well surrounded by silicon dioxide barrier layers which are perforated to insure crystal alignment. Berger et al. (U.S. patent application Publication No. US 2003/0049894 A1) discloses resonant interband tunnel devices (RITD) in which the tunnel barrier is separated from the quantum well by a spacer layer. Such a device is a hybrid between the standard Esaki tunnel diode (which is interband) and the RTD, which is intraband.

### SUMMARY OF THE INVENTION

A first object of the present invention is to provide a method of forming an RTD device that is compatible with mainstream CMOS technologies, particularly those that use the technology of silicon-on-insulator (SOI) transistor fabrication.

A second object of the present invention is to provide a method of forming such a device wherein good I-V characteristics, such as high peak-to-valley ratio (PVR), are obtained.

A third object of the invention is to provide a method of forming an RTD device whose barrier layers allow a low band offset between the barrier material and the well material.

A fourth object of the present invention is to provide the RTD device so formed.

The similarities between the fabrication methods of the present invention and those of double gate (DG) SOI transistor formation are striking, since the quantum well of the RTD is sandwiched between two dielectric barrier layers in the same way as the channel layer of the DG transistor is sandwiched between the two gate dielectric layers. In particular, fabrication methods will include the deposition of dielectric layers around a thin silicon film that can be oriented in either a vertical or horizontal direction (for DG SOI similarities, see H.-S. P. Wong et al., “Self-aligned (top and bottom) double gate MOSFET with a 25 nm. thick silicon channel.” 1997 IEDM Technical Digest). The objects of the invention will be achieved by means of the formation of a vertical or lateral double barrier RTD within a silicon-on-insulator (SOI) structure using low band-offset-to-silicon dielectric materials as barrier materials and an ultra-thin silicon layer, or a Ge or SiGe layer, as a well. Given that the band offset between SiO₂ and silicon is 3.1 eV, dielectric materials (and their offsets in eV) fulfilling the low-offset criterion include Si₃N₄ (2.1), Al₂O₃ (2.4), Y₂O₃ (2.3), Ta₂O₅ (1-1.5), TiO₂ (1.2), HfO₂ (1.9), Pr₂O₃(1.0), ZrO₂ (1.4) and their alloys and laminates. These low band offset materials are also high-k dielectrics which are being extensively studied and now used as gate dielectrics in the context of other types of solid state devices, as thoroughly discussed in G. D. Wilk, R. M. Wallace and J. M. Anthony, “High-k gate dielectrics: Current status and materials properties considerations,” J. Appl. Phys.,. vol. 89, No. 10, 15 May 2001, pp 5243-5275.

### BRIEF DESCRIPTION OF THE DRAWINGS

The objects, features, and advantages of the present invention are understood within the context of the Description of the Preferred Embodiment as set forth below. The Description of the Preferred Embodiment is understood within the context of the accompanying figures, wherein:

FIG. 1 illustrates the schematic view of the conduction band diagram of a double barrier resonant tunnel diode without bias voltage.

FIG. 2 illustrates the schematic view of the double barrier resonant tunnel diode of FIG. 1 with an applied bias voltage.

FIG. 3 illustrates the schematic view of the typical I-V characteristic of the resonant tunnel diode.

FIG. 4 illustrates graphically a simulated RTD drive current improvement by reducing the conduction band offset values.

FIG. 5 illustrates the typical I-V characteristic of low band offset dielectric/Si RTD with different Si thickness. Solid and dashed lines are I-V curves simulated on RTD with Si well thickness of 5 nm and 10 nm, respectively.

FIG. 6 illustrates the typical I-V characteristic of low band offset dielectric/Si RTD with different Si well orientations. Solid and dashed lines are I-V curves simulated on RTD with Si (110) and (100) well, respectively.

FIG. 7 illustrates the schematic view of a thin vertical silicon film covered on its sides with the low band offset dielectric of the present invention and a polysilicon contact layer to form an RTD.

FIGS. 8a-d illustrates in schematic views, the formation of the back side etched horizontal silicon film RTD using the low band offset dielectric of the present invention.

FIGS. 9a-c illustrates in schematic views, the formation of a top side etched thin silicon film RTD with low band offset dielectric used in accord with the present invention.

### DESCRIPTION OF THE PREFERRED EMBODIMENTS

The preferred embodiments of the present invention include three methods of forming a RTD structure using low band offset dielectrics as barrier layers formed adjacent to and in contact with a quantum well formed of a silicon layer. In the case of the silicon layer, the fabrication process will begin most advantageously with a silicon-on oxide (SOI) substrate, which is a substrate of choice in many fabrication processes. However, the method to be presented can also be applied advantageously to Ge quantum wells and to SiGe quantum wells, in which cases the substrate of choice would be a Ge-on-oxide (GOI) substrate or a SiGe-on-oxide substrate. It is also envisioned that other semiconductor materials could be formed into quantum well structures, in which case other substrates could be employed. Although the examples to be presented specifically mention Si, Ge and SiGe and although Si is most probbly the most common semiconductor material being employed in semiconductor fabrications, the generality of this method should be remembered.

In RTD structure to be discussed, dielectric materials with lower barrier-to-well band offset values than SiO₂ are used as the barrier materials. This is what is meant by the phrase “low band offset” dielectric materials. From simulation studies, the drive current of the RTD structure can be increased as much as 3-6 orders of magnitude by using the dielectric materials described earlier. The RTD of the present invention, using the low band offset dielectric-to-Si system (in all the following, Ge or SiGe, can replace the Si, with different effective electron and hole masses being noted), also demonstrates good I-V characteristics, such as a high peak to valley ratio (PVR). Within the methods of the preferred embodiments, the peak to valley ratio and voltage swing of RTDs on low band offset dielectric-to-Si can be optimized by tuning the thickness of dielectric and Si quantum well, the dielectric band offsets, the Si crystalline orientation and further by employing Ge or SiGe well materials. The silicon quantum well can easily be integrated and fabricated with the conventional SOI technology, such as CMOS DG (double gate) SOI technology.

The principle of the RTD has been explained in the literature by Esaki et al. as cited above and is further elaborated by Jian Ping Sun, George I Haddad, Pinaki Mazumder and Joel N. Schulman, “Resonant Tunneling Diodes: Models and Properties,” Proc. IEEE, Vol. 86, No. 4, April 1998, pp. 641-661. In the preferred embodiment of the present invention, low band offset dielectrics are used as a barrier layer and Si (or SiGe or Ge) are used as well materials.

Referring first to FIG. 1, there is shown schematically the conduction band energy diagram of an RTD structure at equilibrium (no applied bias voltage). The vertical direction refers to the energy of an electron within the structure, and the horizontal direction (left-to-right) represents position within the structure. The basic structure is that of a double barrier surrounding a quantum well. Regions 2a and 2b indicate the barrier regions. The top of the barrier is its conduction band edge. Regions 1a and 1b represent two conducting contacts, which can be metal or doped polysilicon (n⁺ doped, for example), for injecting and extracting electrons, the lower horizontal lines (212) and (213) being their conduction band edges (lowest energy of conduction electrons). The dotted lines (210) and (211) represent the Fermi levels in the contact material and the double-headed arrow (215) in region 1a indicates the energy that an electron at the Fermi energy (the most energetic conduction electron) would need to overcome the barrier without tunneling. Region 3 is the quantum well, formed of Si in the preferred embodiment, and of thickness t_{Si} as indicated in the legend. The two horizontal lines within the well (220) and (221) represent exemplary bound state energy levels within the well. As is known from quantum mechanics, the existence of such bound state energy levels is indicative of the fact that the wavefunctions of electrons within the well having that energy demonstrate constructive interference and persist as bound states.

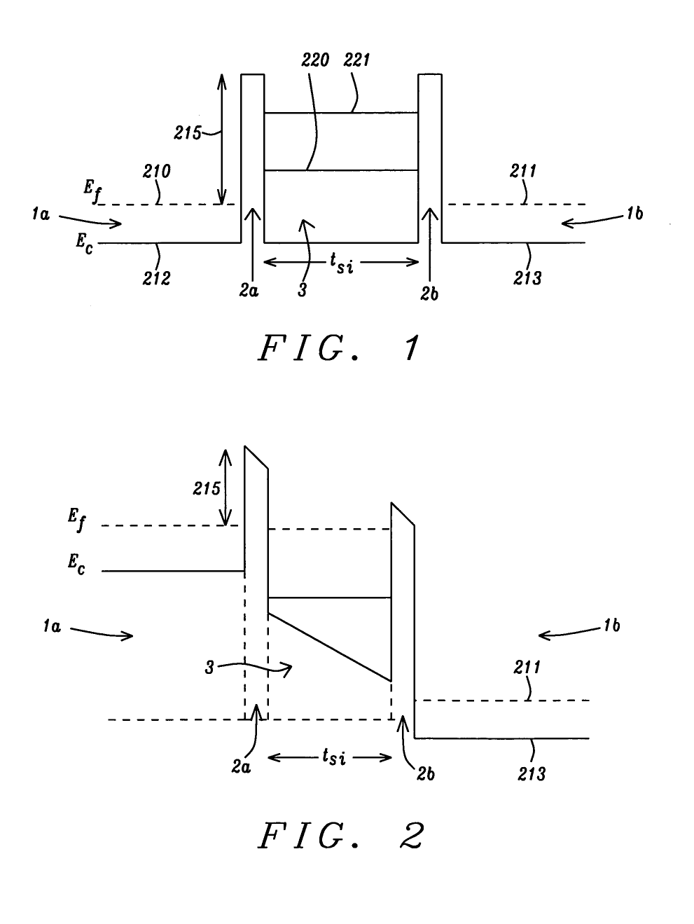

Referring next to FIG. 2, there is shown the energy diagram of the RTD structure of FIG. 1 wherein a bias voltage (Vₐₚ) has been applied between the regions 1a and 1b. The effect of the bias voltage is to align the Fermi energy of the region 1a electrode (210) with the second energy level (221) of the quantum well, thereby enhancing tunneling of conduction electrons from the electrode into the well. The band offset is the height of the barrier relative to the conduction band edge of the Si. All other reference numerals are identical to those in FIG. 1.

Referring next to FIG. 3, there is seen the typical RTD I-V curve which exhibits the region of negative differential resistance (NDR) surrounded by a dotted closed curve (5). The basic parameters for a RTD device are indicated in the figure and include: the peak current (I_{P}), peak voltage (V_{P}), valley current (I_{V}), valley voltage (V_{V}), the peak-to-valley ratio (PVR), and the region (6) approaching the voltage swing (V_{S}), which is defined as the voltage at which the current reaches second I_{P}. Desired RTD characteristics can be analyzed in terms of the above parameters.

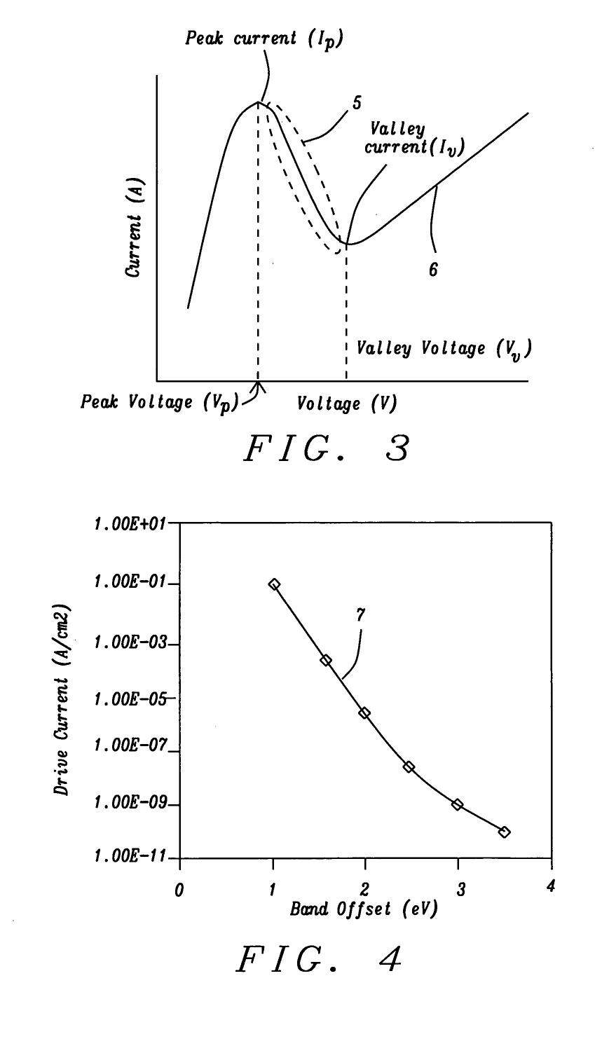

Referring next to FIG. 4, there is shown simulation results indicating dependence of the valley current (I_{V}) (7) on the band offset values between the barrier and Si well. It is found that the dielectric-to-Si band offset can be used to tune the drive current effectively. The current can be improved by as much as 2 orders of magnitude when the band offset value is reduced by 0.5 eV. Therefore, this invention proposes the use of dielectric materials which have lower band offsets with Si, as the barrier layers in RTD. The candidate dielectric materials include Si₃N₄, HfO₂, ZrO₂, Y₂O₃, Pr₂O₃, TiO₂, Al₂O₃, Ta₂O₅, their alloys or laminates, with band offsets values in 1-2 eV range as noted in G. D. Wilk et al., cited above. Compared with SiO₂ (band offset 3.1 eV), the drive current improvement is expected to be 3-6 orders in magnitude. As a result, the proposed RTD structure made on low band offset dielectric-to-Si system has the advantages of significant drive current improvement over the SiO₂-to-Si system without degrading the PVR characteristic.

The PVR is another important parameter for RTD. Here, we also propose several methods to optimize the PVR. One approach is the reduction of the Si well thickness. Referring next to FIG. 5, there can be seen the advantage of reducing the well thickness. The solid curve (9) is for a well that is 5nm thick, the dashed curve is for a well that is 10 nm thick. It can be seen, when using thinner well thickness to engineer the sub-band structure, the PVR of the RTD is significantly improved. The use of thin well also increases the voltage swing, which provides another benefit for device integration. The thin well thickness can also minimize the scattering process in the well, which will degrade the peak current and resultantly the PVR.

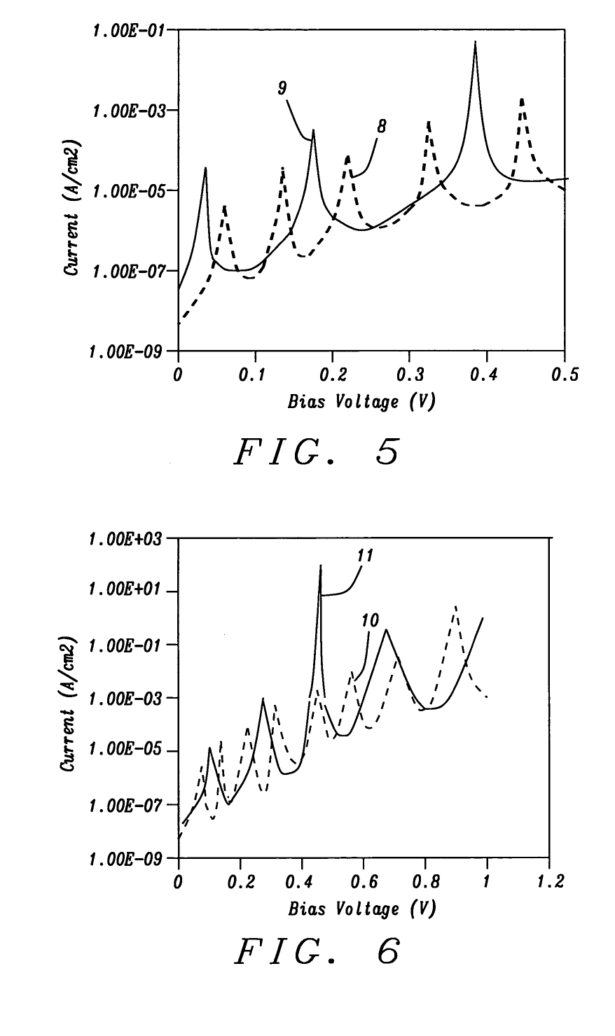

Another approach to optimize the PVR is the fabrication of RTD on a Si well having other crystalline directions than the conventional (100) surface. Referring to FIG. 6, there is seen the I-V characteristics for RTDs with different Si well orientations, the solid curve (11) being a (110) crystalline surface orientation and the dashed curve (10) being the conventional (100) crystalline surface orientation. Compared to the conventional (100) orientation, an RTD with (110) Si well, which can be implemented by the technology used to fabricate FinFETs, can achieve a larger voltage swing and possibility for higher PVR. This is due to their different electron effective mass values and the effect of those mass values on the resultant energy levels and electron quantization behavior in the well. Such a sub-band engineering approach to optimize the RTD performance can also be achieved by using Ge or SiGe as the well materials. The technology associated with FinFET fabrication is well known and is reported, for example, in Xuejue Huang et al. “Sub 50-nm FinFET: PMOS” 80 IEEE Transactions On Electron Devices, Vol. 48, No. 5, May 2001.

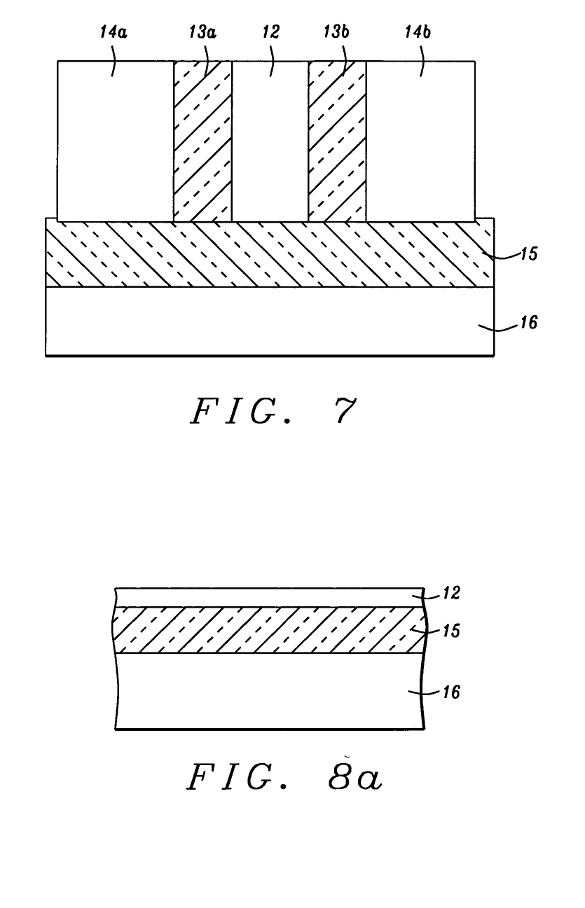

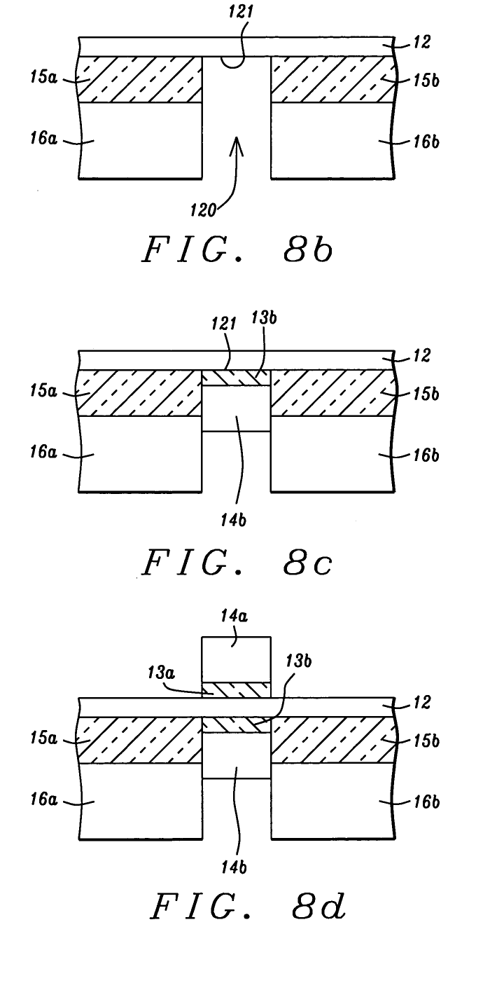

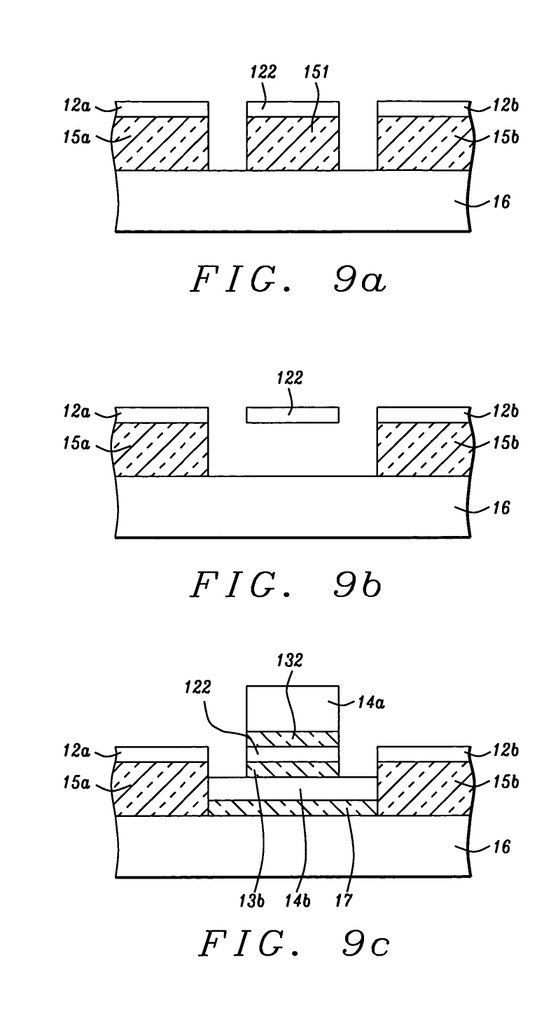

FIGS. 7, 8 and 9, respectively, schematically illustrate methods of fabricating the invention in which the planes of the RTD layers are in the vertical (FIG. 7) and horizontal (FIGS. 8 and 9) directions. Referring first to FIG. 7, there is shown a substrate (16) and an isolating layer or a series of isolating layers (15) formed upon the substrate. The substrate has a substantially planar horizontal upper surface. A horizontally disposed RTD fabrication of vertical layers is then formed on the isolating layer as a series of vertically planar layers in the following manner. First, there is formed a thin vertical layer of monocrystalline silicon (12) (equivalently, Ge or SiGe), between approximately 2 and 25 nm in width and in any of the preferred crystallographic planar orientations such as (100), (110) or (111), with approximately 10 nm in width (or 5 nm in width, to obtain reduced scattering and other energy levels) being preferred. This layer is patterned using photolithography techniques well known in the art from the methodology of forming other horizontally disposed, vertically layered device structures such as FinFETs. In the FinFET devices this layer is known as the Fin and it can be patterned using e-beam, optical and phase-shift masking optical lithography and in combination with resist or hard mask, such as oxide layer, trimming. This trimming will be necessary only when the lithography range is smaller than the device dimension range. Afterward, such Fin patterns are transferred onto the silicon substrate using silicon dry etch techniques. The vertical silicon pattern is smoothed by methods such as oxidation and wafer cleaning processes.

This layer, patterned as indicated above and having the preferred widths and crystallographic orientations, forms the quantum well in the RTD structure. It is understood that the width of the well in this and other embodiments is sufficient to form a plurality of electron bound states (at least one bound state) and associated energy levels in order to provide the required resonant tunneling. It is also understood that electron scattering within the well can be reduced by reducing the thickness of the well and that such reductions can be used to optimally tune the performance characteristics of the RTD device. Apart from this, an n-type or a p-type doping with doping level between approximately 10⁻¹⁶ to 10⁻¹⁹ cm⁻³ is used to further tune the performance characteristics of the RTD device. A thin layer (13) of low band offset dielectric material, such as Si₃N₄, HfO₂, ZrO₂, Y₂O₃, Pr₂O₃, TiO₂, Al₂O₃, Ta₂O₅, their alloys or laminates as discussed earlier, is deposited by a method such as chemical-vapor deposition (CVD), atomic-layer deposition (ALD), or sputtering, on each side of the thin silicon film to a thickness between approximately 0.5 nm. and 5.0 nm. This layer will serve as the tunneling barrier. Subsequent to this deposition, a layer of n+ polysilicon (heavily n-doped polysilicon) or an ohmic metal contact (14) is deposited on the barrier layer (13) to a thickness approximately 0.5 μm using methods such as e-beam evaporation, CVD, ALD, or sputtering. This contact material has a lower conduction band level than the dielectric material and thereby forms the offset barrier for the electron moving from the contact to the quantum well structure. When a bias voltage is applied between the contacts (14), there will be obtained the NDR characteristics of FIG. 3, which are a result of the tunneling across the dielectric material to the quantum confined structure (quantum well), which has the appropriate resonant states. Similar techniques can also be applied when Ge and SiGe materials are used to form the quantum well, in which case the initial substrate would be an equivalent Germanium-on-insulator (GOI) or SiGe-on insulator formation.

Referring next to FIG. 8a, there is seen the first step in producing an alternative embodiment of the invention. In this embodiment, the silicon layer forming the quantum well will be is formed horizontally by exposing and thinning the silicon layer within a silicon-on insulator (SOI) substrate. The SOI substrate includes a lower silicon layer (16), a bottom oxide layer (BOX) (15) and an upper silicon layer (12) of monocrystalline silicon, which may be doped, formed on the BOX.

Referring next to FIG. 8b, there is shown in schematic cross-section the SOI substrate of FIG. 8a on which a back-side oxide-etch has formed a trench (120) through the lower silicon layer (16b and 16a) and BOX (15b and 15a), thereby exposing the lower surface (121) of the upper silicon layer (12), of the SOI structure. Referring next to FIG. 8c, there is shown the deposition of a lower dielectric barrier layer (13b) of low band offset material such as the high-k dielectrics Si₃N₄, HfO₂, ZrO₂, Y₂O₃, Pr₂O₃, TiO₂, Al₂O₃, Ta₂O₅, their alloys or laminates, on the exposed silicon surface (121). The dielectric layer is deposited to a thickness between approximately 0.5 nm and 5.0 nm. These particular materials are high-k dielectrics, but other suitable dielectric barrier layer materials with low band offsets can be appropriately used. A conducting contact layer, such as heavily doped polysilicon or metal is then deposited on the barrier layer (14b).

Referring to FIG. 8d, there is shown the application of a similar sequence of steps to the upper silicon (12) surface. First the silicon layer is thinned by a silicon etch applied to the upper silicon surface. The silicon etch (not shown) thins the silicon appropriately to form a quantum well layer (12), the appropriate thickness being between approximately 2 nm and 25 nm, with approximately 10 nm being preferred. A layer of low band offset dielectric (13a), substantially identical to that applied to the bottom silicon surface (13b), is deposited on the top surface of the thin silicon film. A layer of conducting material, such as metal or heavily doped semi-conducting material (14a) now forms the top contact layer. The buried dielectric layer (15a and b), laterally disposed to either side of the trench within which is the RTD formation can be used to insulate the device from surrounding devices.

Referring to FIGS. 8a, 9a-c, there is shown the formation of another alternative embodiment of the invention also beginning with an SOI substrate as shown in FIG. 8a. Referring next to FIG. 9a, there is shown in cross-section the SOI substrate wherein a trench having an incompletely square perimeter has been vertically etched around and through the upper silicon layer (12a and b) and BOX (15a and b), exposing an upper surface of the lower silicon substrate (16). A substantially square (in horizontal cross-section) segment of the upper silicon layer (122) remains, supported by a portion of the BOX (151) beneath it. This silicon segment, when appropriately thinned will form the quantum well in the final RTD device.

Referring next to FIG. 9b, there is shown in cross-section that the portion of the BOX ((151) in FIG. 9a) has been removed by a lateral oxide etch (using an etchant such as HF), leaving the silicon well segment (122) remaining.

Referring to FIG. 9c, there is shown a sequence of layer depositions both above and beneath the silicon segment (122). The depositions beneath (122) use lateral deposition methods such as CVD which are capable of producing depositions beneath an overhead layer. The sequence of depositions beneath (122) include, first, deposition of a lower dielectric barrier layer (13b) formed to a thickness between approximately 0.5 nm and 5.0 nm, on the underside of the silicon segment (122), followed by deposition of a conducting layer (14b) formed on the underside of the barrier layer. The deposition process that forms the lower barrier layer (13b) also produces a layer of the same material (17) on the lower silicon substrate (16) (or on any remnant of the original BOX layer that may remain on the silicon substrate). This additional deposited layer (17) serves advantageously as an isolating dielectric layer between the conducting layer (14b) and the silicon substrate (16).

A second sequence of depositions above (122) follows a thinning (not shown) of the silicon segment (122) to proper well thickness between approximately 2 nm and 25 nm by a silicon etch. The second sequence then produces the following layers on the upper surface of the thinned silicon segment (122): first, an upper dielectric barrier layer (13a) is formed over the top surface of the silicon segment and then an upper conducting layer (14a) is formed on the upper dielectric barrier layer. A patterning then produces the final configuration as shown, in which the upper conducting layer (14a), the upper barrier layer (13a), the silicon well layer (122) and the lower barrier layer (13b) have a common horizontal square cross-section and co-planar vertical sides. This patterned configuration rests on the lower conducting layer (14b).

The top and bottom dielectric tunneling barrier layers (13a) and (13b) are formed to a thickness between approximately 0.5 and 3.0 nm. A heavily doped semi-conductor or other conductive material (such as a metal) (14a) and (14b) can be used for the top and bottom contacts. As noted, the bottom contact is isolated from the substrate material (16) using by the isolating dielectric layer (17). The isolating layer as well as the tunneling barrier layers can be formed of low band offset dielectric materials such as the high k materials Si₃N₄, HfO₂, ZrO₂, Y₂O₃, Pr₂O₃, TiO₂, Al₂O₃, Ta₂O₅, their alloys or laminates, formed to a thickness between approximately 0.5 and 3.0 nm. The proposed low band offset dielectric/Si RTD of FIGS. 7, 8 and 9 are easily integrated within the Si-based IC technology. Its fabrication is compatible with the current CMOS technology.

As is understood by a person skilled in the art, the preferred embodiment of the present invention is illustrative of the present invention rather than being limiting of the present invention. Revisions and modifications may be made to methods, processes, materials, structures, and dimensions through which is formed an RTD device in either a horizontal or vertical configuration having low band offset barrier layers, while still providing an RTD device in either horizontal or vertical configuration having low band offset barrier layers, formed in accord with the present invention as defined by the appended claims.

1. A resonant tunneling diode (RTD) using low band offset dielectric material as double barrier layers and having a vertical layer configuration comprising:
a substrate having a substantially planar horizontal surface;
a horizontally disposed configuration of vertical layers formed on said substrate, said layers being perpendicular to said horizontal surface, said configuration further comprising:
a quantum well layer formed of a semiconductor material, said layer being vertical, having parallel planar vertical sides and being formed to a first thickness;
a tunneling barrier layer formed on each side of said quantum well layer, each said barrier layer being formed, to a second thickness, of a dielectric material characterized by a low band offset relative to the conduction band edge of said semiconductor material; and
an adjacent conducting contact layer being formed on each said tunneling barrier layer.

2. The RTD of claim 1 wherein said quantum well semiconductor material is monocrystalline Si, Ge or SiGe.

3. The RTD of claim 1 wherein said quantum well layer is oriented so that its vertical sides are any preferred crystallographic plane.

4. The RTD of claim 3 wherein said low band offset dielectric material is the high-k dielectric material Si₃N₄, HfO₂, ZrO₂, Y₂O₃, Pr₂O₃, TiO₂, Al₂O₃, or Ta₂O₅, or their alloys or laminates

5. The RTD of claim 4 wherein said dielectric material is formed to a second thickness of between approximately 0.5 nm. and 5.0 nm.

6. The RTD of claim 5 wherein the quantum well layer is monocrystalline Si and the crystallographic planes are the 100, 110 or 111 crystallographic planes.

7. The RTD of claim 6 wherein said Si quantum well layer is formed to a first thickness between approximately 2 nm. and 25 nm. and wherein said layer is characterized by at least one electron bound state and associated bound state energy.

8. The RTD of claim 7 wherein the silicon quantum well layer is doped with either n-type or p-type doping to a dopant concentration between approximately 10⁻¹⁶ and 10⁻¹⁹ cm⁻³.

9. The RTD of claim 1 wherein each said conducting layer is a layer of n+ doped polysilicon or a layer of metal.

10. The RTD of claim 1 wherein said substrate is a SOI, GOI or SiGe-on oxide substrate and wherein an isolating layer is interposed between said substrate and said horizontally disposed configuration.

11. A resonant tunneling diode (RTD) using low band offset dielectric material as double barrier layers comprising:
a substrate;
a patterned configuration of planar horizontal layers formed on said substrate and extending partially within said substrate, said configuration having substantially planar vertical sides and the configuration further comprising:
a quantum well layer formed of a semiconductor material, said layer being characterized by upper and lower planar horizontal surfaces and a first thickness;
an upper tunneling barrier layer formed on said upper surface of said quantum well layer and a lower tunneling barrier layer formed on said lower surface of said quantum well layer, each said barrier layer having a substantially equal second thickness and each barrier layer being formed of a dielectric material characterized by a low band offset relative to said quantum well layer;
an upper conducting layer formed on said upper tunneling barrier layer and a lower conducting layer formed beneath said lower tunneling barrier layer and extending substantially into an insulating layer within said substrate; and
said insulating layer being laterally disposed to said lower conducting layer and contacting vertical sides of said conducting layer.

12. The RTD of claim 11 wherein said quantum well semiconductor material is monocrystalline Si, Ge or SiGe.

13. The RTD of claim 12 wherein said quantum well layer is monocrystalline silicon and it is formed to a first thickness between approximately 2 nm. and 25 nm. and wherein said layer is characterized by at least one electron bound state and associated bound state energy.

14. The RTD of claim 13 wherein the silicon quantum well layer is doped with either n-type or p-type doping to a dopant concentration between approximately 10⁻¹⁶ and 10⁻¹⁹ cm⁻³.

15. The RTD of claim 12 wherein said low band offset dielectric material is the high-k dielectric material Si₃N₄, HfO₂, ZrO₂, Y₂0₃, Pr₂O₃, TiO₂Al₂O₃, or Ta₂O₅, or their alloys or laminates

16. The RTD of claim 15 wherein said dielectric material is formed to a second thickness of between approximately 0.5 nm. and 5.0 nm.

17. The RTD of claim 11 wherein each said conducting layer is a layer of n+ doped polysilicon or a layer of metal.

18. A resonant tunneling diode (RTD) using low band offset dielectric material as double barrier layers comprising:
a substrate;
a patterned configuration of planar horizontal layers formed within an opening in said substrate, said configuration further comprising:
a quantum well layer formed of semiconductor material, said layer being characterized by upper and lower planar horizontal surfaces and a first thickness;
an upper tunneling barrier layer formed on said upper surface and a lower tunneling barrier layer formed on said lower surface of said quantum well layer, each said barrier layer having a substantially equal second thickness and each barrier layer being formed of a dielectric material characterized by a low band offset relative to said quantum well layer;
an upper conducting layer formed on said upper tunneling barrier layer and a lower conducting layer formed on said lower tunneling barrier layer; and
an isolating dielectric layer formed between said lower conducting layer and said substrate; and, wherein said upper conducting layer, said upper barrier layer, said silicon well layer and said lower barrier layer have been patterned to form co-planar vertical sides and a common horizontal cross-section which is substantially square.

19. The RTD of claim 18 wherein said quantum well semiconductor material is monocrystalline Si, Ge or SiGe.

20. The RTD of claim 18 wherein said quantum well layer is monocrystalline silicon and it is formed to a first thickness between approximately 2 nm. and 25 nm. and wherein said layer is characterized by at least one electron bound state and associated bound state energy.

21. The RTD of claim 20 wherein the silicon quantum well layer is doped with either n-type or p-type doping to a dopant concentration between approximately 10⁻¹⁶ and 10⁻¹⁹ cm⁻³.

22. The RTD of claim 19 wherein said low band offset dielectric material is the high-k dielectric material Si₃N₄, HfO₂, ZrO₂, Y₂0₃, Pr₂O₃, TiO₂, Al₂O₃, or Ta₂O₅, or their alloys or laminates.

23. The RTD of claim 22 wherein said dielectric material is formed to a second thickness of between approximately 0.5 nm. and 5.0 nm.

24. The RTD of claim 18 wherein each said conducting layer is a layer of n+ doped polysilicon or a layer of metal.

25. A method of forming a resonant tunneling diode (RTD) having tunnel barrier layers formed of low band offset dielectric material and a vertical layer configuration comprising:
providing a substrate having a substantially planar horizontal surface;
forming a horizontally disposed configuration of vertical layers on said substrate, said layers being perpendicular to said horizontal surface, the formation of said configuration further comprising:
forming, by photolithographic patterning and etching, a quantum well layer of a monocrystalline semiconductor material, said layer being vertical, having parallel planar vertical sides and being formed to a first thickness;
smoothing the vertical sides of said quantum well layer;
forming, by a process of CVD, ALD or sputtering, a tunneling barrier layer on each side of said quantum well layer, each said barrier layer being formed, to a second thickness, of a dielectric material characterized by a low band offset relative to the conduction band edge of said quantum well layer;
forming a conducting contact layer on each said tunneling barrier layer; and
smoothing the sides of each said contact layer.

26. The method of claim 25 wherein said substrate is a SOI substrate, a GOI substrate or a SiGe-on-insulator substrate.

27. The method of claim 25 wherein said semiconductor material is monocrystalline Si, Ge or SiGe.

28. The method of claim 27 wherein said low band offset dielectric material is the high-k material Si₃N₄, HfO₂, ZrO₂, Y₂O₃, Pr₂O₃, TiO₂, Al₂O₃, or Ta₂O₅, their alloys or laminates

29. The method of claim 25 wherein said quantum well layer is oriented so that its vertical sides are in any of its preferred crystallographic planes.

30. The method of claim 29 wherein the layer is Si and its crystallographic planes are the 100, 110 or the 111 crystallographic planes.

31. The method of claim 30 wherein said silicon quantum well layer is formed to a first thickness between approximately 2 nm. and 25 nm. and wherein said layer is characterized by at least one electron bound state and associated bound state energy.

32. The method of claim 31 wherein the silicon quantum well layer is doped with either n-type or p-type doping to a dopant concentration between approximately 10⁻⁶ and 10⁻¹⁹ cm⁻³.

33. The method of claim 28 wherein said dielectric material is formed to a second thickness of between approximately 0.5 nm. and 3.0 nm.

34. The method of claim 25 wherein said conducting layer is a layer of n+ doped polysilicon or a layer of metal.

35. A method of forming a low band offset double barrier resonant tunneling diode (RTD) having low band offset dielectric material for the barrier layers comprising:
providing a substrate including an upper monocrystalline semiconductor layer, a lower semiconductor layer and a buried oxide (BOX) layer formed between said upper and lower semiconductor layers, wherein said upper semiconductor layer has an upper surface and a lower surface and wherein said buried oxide layer is formed between the lower surface of said upper and said lower semiconductor layers;
etching a trench through said lower semiconductor layer and said BOX layer to expose a portion of said lower surface of said upper semiconductor layer;
forming a lower tunneling barrier layer on said exposed portion of said lower surface of said upper semiconductor layer, said barrier layer being formed of a dielectric material characterized by a low band offset relative to said upper semiconductor layer;
forming a lower conducting layer on said lower barrier layer;
reducing the thickness of said upper semiconductor layer by etching away a portion of said upper surface of said upper semiconductor layer that is vertically above said lower exposed semiconductor surface, said reduction in thickness producing a quantum well;
forming an upper tunneling barrier layer on said etched upper semiconductor surface said layer being formed of a dielectric material characterized by a low band offset relative to said silicon layer; and
forming an upper conducting layer on said upper tunneling barrier layer.

36. The method of claim 35 wherein said substrate is a SOI substrate, a GOI substrate or a SiGe-on-insulator substrate.

37. The method of claim 35 wherein said semiconductor material is monocrystalline Si, Ge or SiGe.

38. The method of claim 37 wherein said low band offset dielectric material is the high-k material Si₃N₄, HfO₂, ZrO₂, Y₂0₃, Pr₂O₃, TiO₂, Al₂O₃, or Ta₂O₅, their alloys or laminates.

39. The method of claim 30 wherein said quantum well layer is a layer of silicon formed to a first thickness between approximately 2 nm. and 25 nm. and wherein said layer is characterized by at least one electron bound state and associated bound state energy.

40. The method of claim 39 wherein the silicon quantum well layer is doped with either n-type or p-type doping to a dopant concentration between approximately 10⁻¹⁶ and 10⁻¹⁹ cm⁻³.

41. The method of claim 38 wherein said dielectric material is formed to a second thickness of between approximately 0.5 nm. and 3.0 nm.

42. The method of claim 35 wherein said conducting layer is a layer of n+ doped polysilicon or a layer of metal.

43. A method of forming a resonant tunneling diode (RTD) having low band offset dielectric material for the barrier layers comprising:
providing a substrate including an upper semiconductor layer, a lower semiconductor layer and a buried oxide (BOX) layer formed between said upper and lower semiconductor layers, wherein said upper semiconductor layer has an upper surface and a lower surface and wherein said buried oxide layer is formed between the lower surface of said upper semiconductor layer and said lower semiconductor layer;
forming a patterned configuration of planar horizontal layers on the lower semiconductor layer of said substrate, said formation further comprising:
forming a patterned layer of the upper semiconductor layer, by vertically etching a trench surrounding a substantially square region of said upper layer, the trench passing completely through said BOX layer and terminating at said lower semiconductor layer, and then removing all portions of said BOX layer directly beneath said patterned upper layer by laterally etching said BOX layer;
forming a lower tunneling barrier layer on the lower surface of said patterned layer by a lateral deposition, said barrier layer being formed of a dielectric material characterized by a low band offset relative to said upper semiconductor layer; said deposition also forming a dielectric isolation layer on said lower semiconductor layer;
forming a lower conducting layer on said lower tunneling barrier layer by lateral deposition, said conducting layer being, thereby, between said tunneling barrier layer and said isolation layer;
thinning said patterned upper semiconductor layer to form a quantum well layer;
forming an upper tunneling barrier layer on the upper surface of said quantum well layer by deposition, said upper tunneling barrier layer being formed of a dielectric material characterized by a low band offset relative to said silicon layer;
forming an upper conducting layer on said upper tunneling barrier layer by deposition;
patterning said upper conducting layer to produce a layered configuration of substantially square horizontal cross-section and substantially planar vertical sides, said layered configuration including the lower barrier layer, the upper silicon layer, the upper barrier layer and the upper conducting layer.

44. The method of claim 43 wherein said tunneling barrier layers and said conducting layers are deposited by CVD.

45. The method of claim 43 wherein said substrate is a SOI substrate, a GOI substrate or a SiGe-on-insulator substrate.

46. The method of claim 43 wherein said semiconductor material is monocrystalline Si, Ge or SiGe.

47. The method of claim 43 wherein said low band offset dielectric material is the high-k material Si₃N₄, HfO₂, ZrO₂, Y₂O₃, Pr₂O₃, TiO₂, Al₂O₃, or Ta₂O₅, their alloys or laminates.

48. The method of claim 47 wherein said quantum well layer is a layer of silicon formed to a first thickness between approximately 2 nm. and 25 nm. and wherein said layer is characterized by at least one electron bound state and associated bound state energy.

49. The method of claim 48 wherein the silicon quantum well layer is doped with either n-type or p-type doping to a dopant concentration between approximately 10⁻¹⁶ and 10⁻¹⁹ cm⁻³.

50. The method of claim 47 wherein said dielectric material is formed to a second thickness of between approximately 0.5 nm. and 3.0 nm.

51. The method of claim 43 wherein said conducting layer is a layer of n+ doped polysilicon or a layer of metal.
